(19) United States
(12) Patent Application Publication
(10) Pub. No.: US 2019/0348473 A1
(43) Pub. Date: Nov. 14, 2019

(54) FLEXIBLE SUBSTRATE, MANUFACTURING METHOD THEREOF AND TOUCH DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Xiangyang XU, Shenzhen (CN)

(21) Appl. No.: 16/152,765

(22) Filed: Oct. 5, 2018

Related U.S. Application Data
(63) Continuation of application No. PCT/CN2018/092350, filed on Jun. 22, 2018.

(30) Foreign Application Priority Data
May 14, 2018 (CN) 201810458414.7

(51) Int. Cl. H01L 27/32; H01L 51/00; H01L 51/56; G06F 3/044; G06F 3/041

(52) U.S. Cl. CPC H01L 27/323; H01L 51/0097; H01L 51/56; G06F 2203/04103; G06F 3/0412; G06F 2203/04102; G06F 3/044

(57) ABSTRACT

Provided are a flexible substrate, a manufacturing method thereof and a touch display panel. The touch display panel includes a flexible substrate, a driving element layer, an organic light emitting functional layer and thin film encapsulation layer located on the flexible substrate. The flexible substrate includes at least two flexible substrate layers and a touch circuit disposed between the at least two flexible substrate layers. A thickness of the touch display panel can be reduced to improve a production yield of the touch display panel.

### CROSS-REFERENCE TO RELATED APPLICATION

This application is a continuing application of PCT Patent Application No. PCT/CN2018/092350 entitled “Flexible substrate, manufacturing method thereof and touch display panel”, filed on Jun. 22, 2018, which claims priority to Chinese Patent Application No. 201810458414.7, filed on May 14, 2018, both of which are hereby incorporated in its entireties by reference.

### FIELD OF THE INVENTION

The present invention relates to a display field, and more particularly to a flexible substrate, a manufacturing method thereof and a touch display panel.

### BACKGROUND OF THE INVENTION

As a new generation display technology, AMOLED (Active-matrix organic light emitting diode) display panel has low power consumption, high color gamut, high brightness, high resolution, wide viewing angle and high response speed. The advantages are therefore highly favored by the market. The flexible AMOLED display panel even has the advantages of being curled, folded and worn.

The manufacturing steps of the existing flexible display panel are as follows: First, a rigid carrier substrate, such as glass or steel plate, is provided, and then a bonding layer is formed on the rigid carrier substrate, and then a flexible substrate such as PI (polyimide) or PET (Polyester resin) is deposited or attached on the bonding layer, and then patterned driving element and display element are formed on the flexible substrate, and then the display element is encapsulated to obtain an organic light emitting functional layer, and finally, the flexible substrate and the rigid substrate are separated to obtain the flexible display substrate. The general flexible display substrate also needs to integrate the touch function. Currently, mainstream touch functions include: In cell, On cell and OGS (One Glass Solution). In cell is integrated with touch sensing in the internal circuit of flexible display substrate; On cell is to make touch sensing on the surface of flexible display substrate; OGS is an external touch technology, which is to attach a touch panel to the flexible display substrate. All three technologies will lose the panel yield and increase the thickness of the panel. As shown in FIGS. 1 to 3, the In cell, On cell, and OGS touch flexible display panel structures are respectively shown.

### SUMMARY OF THE INVENTION

For solving the aforesaid technical issues, the present invention provides a flexible substrate, a manufacturing method thereof and a touch display panel, which can reduce the thickness of the touch display panel and can improve the production yield of the touch display panel.

The present invention provides a flexible substrate, comprising at least two flexible substrate layers and a touch circuit disposed between the at least two flexible substrate layers.

Preferably, the touch circuit is a self-capacitive touch circuit or a mutual-capacitive touch circuit, and the self-capacitive touch circuit comprises a touch electrode layer, and the mutual-capacitive touch circuit comprises two touch electrode layers.

Preferably, as the touch circuit is the self-capacitive touch circuit, the at least two flexible substrate layers comprise a first flexible substrate layer and a second flexible substrate layer, and the touch electrode layer is arranged between the first flexible substrate layer and the second flexible substrate layer; the touch electrode layer comprises a plurality of touch electrodes.

Preferably, as the touch circuit is a mutual-capacitive touch circuit, the at least two flexible substrate layers comprise a first flexible substrate layer, a second flexible substrate layer and a third flexible substrate layer, and a first touch electrode layer is arranged between the first flexible substrate layer and the second flexible substrate layer, and a second touch electrode layer is arranged between the second flexible substrate layer and the third flexible substrate layer, and a mutual capacitance is formed between the first touch electrode layer and the second touch electrode layer.

Preferably, the touch electrode layer is made of a transparent conductive material, and the flexible substrate layer is made of a polyimide material or a polyester resin material.

Preferably, the transparent conductive material is one of an indium tin oxide material, a carbon nanotube and a nano silver wire material.

The present invention further provides a touch display panel, comprising a flexible substrate, a driving element layer, an organic light emitting functional layer and thin film encapsulation layer located on the flexible substrate;

wherein the flexible substrate comprises at least two flexible substrate layers and a touch circuit disposed between the at least two flexible substrate layers.

Preferably, the touch circuit is a self-capacitive touch circuit or a mutual-capacitive touch circuit, and the self-capacitive touch circuit comprises a touch electrode layer, and the mutual-capacitive touch circuit comprises two touch electrode layers.

Preferably, as the touch circuit is the self-capacitive touch circuit, the at least two flexible substrate layers comprise a first flexible substrate layer and a second flexible substrate layer, and the touch electrode layer is arranged between the first flexible substrate layer and the second flexible substrate layer; the touch electrode layer comprises a plurality of touch electrodes.

Preferably, as the touch circuit is a mutual-capacitive touch circuit, the at least two flexible substrate layers comprise a first flexible substrate layer, a second flexible substrate layer and a third flexible substrate layer, and a first touch electrode layer is arranged between the first flexible substrate layer and the second flexible substrate layer, and a second touch electrode layer is arranged between the second flexible substrate layer and the third flexible substrate layer, and a mutual capacitance is formed between the first touch electrode layer and the second touch electrode layer.

Preferably, the touch electrode layer is made of a transparent conductive material, and the flexible substrate layer is made of a polyimide material or a polyester resin material.

Preferably, the transparent conductive material is one of an indium tin oxide material, a carbon nanotube and a nano silver wire material.

The present invention further provides a manufacturing method of a flexible substrate, comprising:

preparing at least two flexible substrate layers; and

preparing a touch circuit between the at least two flexible substrate layers.

Preferably, the touch circuit is a self-capacitive touch circuit or a mutual-capacitive touch circuit, and the self-capacitive touch circuit comprises a touch electrode layer, and the mutual-capacitive touch circuit comprises two touch electrode layers.

Preferably, as the touch circuit is the self-capacitive touch circuit, preparing the at least two flexible substrate layers; and preparing the touch circuit between the at least two flexible substrate layers comprises: preparing a first flexible substrate layer; preparing a touch electrode layer and a second flexible substrate layer on the first flexible substrate layer, wherein the touch electrode layer is sandwiched between the first flexible substrate layer and the second flexible substrate layer; wherein the touch electrode layer comprises a plurality of touch electrodes;

as the touch circuit is a mutual-capacitive touch circuit, preparing the at least two flexible substrate layers; and preparing the touch circuit between the at least two flexible substrate layers comprises: preparing a first flexible substrate layer; preparing a first touch electrode layer and a second flexible substrate layer on the first flexible substrate layer, wherein the first touch electrode layer is sandwiched between the first flexible substrate layer and the second flexible substrate layer; preparing a second touch electrode layer and a third flexible substrate layer on the second flexible substrate layer, and the second touch electrode layer is sandwiched between the second flexible substrate layer and the third flexible substrate layer; wherein a mutual capacitance is formed between the first touch electrode layer and the second touch electrode layer.

The implementation of the present invention possesses the following results: the flexible substrate and the touch display panel provided by the present invention do not need to separately integrate the touch circuit on the outer side of the flexible substrate, thus inevitably increasing the thickness of the entire touch display panel. By simply integrating the touch circuit in the flexible substrate layer, the thickness of the flexible substrate layer can remain unchanged, but the overall thickness of the touch display panel can be reduced. Meanwhile, the touch circuit can be prepared in the flexible substrate, and then the driving circuit and the organic light emitting functional layer are prepared on the flexible substrate, which can reduce the preparation difficulty of the driving circuit, and thereby improving the production yield of the touch display panel.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a structural diagram of an In cell touch flexible display panel according to the prior art;

FIG. 2 is a structural diagram of an On cell touch flexible display panel according to the prior art;

FIG. 3 is a structural diagram of an OGS touch flexible display panel according to the prior art;

FIG. 4 is a structural diagram of an integrated touch circuit in a flexible substrate according to one embodiment of the present invention;

FIG. 5 is a structural diagram of an integrated touch electrode in a flexible substrate according to one embodiment of the present invention;

FIG. 6 is a structural diagram of an integrated touch electrode in a flexible display panel according to another embodiment of the present invention;

FIG. 7 is a structural diagram of a touch display panel according to the present invention,

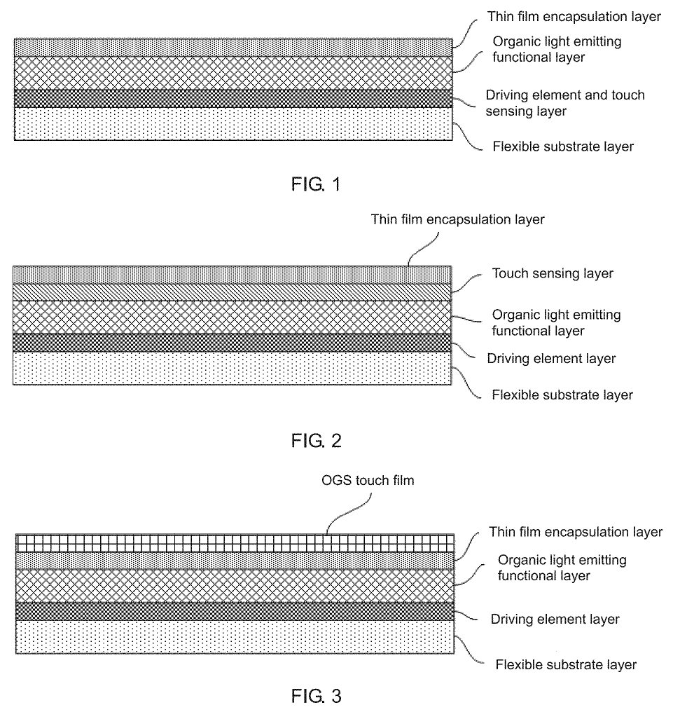

### DETAILED DESCRIPTION OF PREFERRED EMBODIMENTS

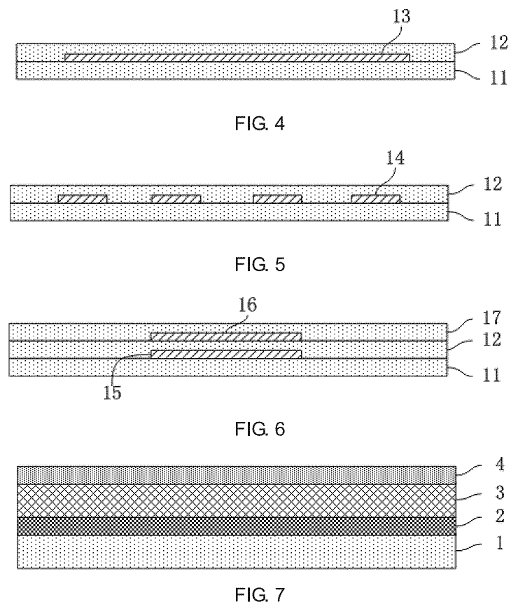

The present invention provides a flexible substrate. The flexible substrate comprises at least two flexible substrate layers and a touch circuit disposed between the at least two flexible substrate layers. For instance, in one embodiment as shown in FIG. 4, the flexible substrate comprises a first flexible substrate layer 11 and a second flexible substrate layer 12, and the touch circuit 13 is arranged between the first flexible substrate layer 11 and the second flexible substrate layer 12.

The touch circuit is a self-capacitive touch circuit or a mutual-capacitive touch circuit, and the self-capacitive touch circuit comprises a touch electrode layer, and the mutual-capacitive touch circuit comprises two touch electrode layers.

Furthermore, as shown in FIG. 5, as the touch circuit is the self-capacitive touch circuit, the at least two flexible substrate layers comprise a first flexible substrate layer 11 and a second flexible substrate layer 12, and the touch electrode layer is arranged between the first flexible substrate layer 11 and the second flexible substrate layer 12; the touch electrode layer between the first flexible substrate layer 11 and the second flexible substrate layer 12 comprises a plurality of touch electrodes 14.

Furthermore, as shown in FIG, 6, as the touch circuit is a mutual-capacitive touch circuit, the at least two flexible substrate layers comprise a first flexible substrate layer 11, a second flexible substrate layer 12 and a third flexible substrate layer 17, and a first touch electrode layer 15 is arranged between the first flexible substrate layer 11 and the second flexible substrate layer 12, and a second touch electrode layer 16 is arranged between the second flexible substrate layer 12 and the third flexible substrate layer 17, and a mutual capacitance is formed between the first touch electrode layer 15 and the second touch electrode layer 16.

Furthermore, the touch electrode layer is made of a transparent conductive material, and the flexible substrate layer is made of a polyimide material (PI material) or a polyester resin material (PET material).

Furthermore, the transparent conductive material is one of an indium tin oxide (ITO) material, a carbon nanotube and a nano silver wire material.

The present invention further provides a touch display panel. As shown in FIG. 7, the touch display panel comprises a flexible substrate 1, a driving element layer 2, an organic light emitting functional layer 3 and thin film encapsulation layer 4 located on the flexible substrate 1.

The driving element layer 2, the organic light emitting functional layer 3 and the thin film encapsulation layer 4 are sequentially stacked on the flexible substrate layer of the flexible substrate 1.

The driving element layer 2 is for driving the organic light emitting functional layer 3 to emit light. The organic light emitting functional layer 3 can be divided into a plurality of pixel regions as needed.

The thin film encapsulation layer 4 completely covers the organic light emitting functional layer 3, and can block water vapor and oxygen.

The present invention further provides a manufacturing method of a flexible substrate. The manufacturing method of the flexible substrate comprises:

preparing at least two flexible substrate layers; and

preparing a touch circuit between the at least two flexible substrate layers.

The touch circuit can be a self-capacitive touch circuit or a mutual-capacitive touch circuit, and the self-capacitive touch circuit comprises a touch electrode layer, and the mutual-capacitive touch circuit comprises two touch electrode layers.

As the touch circuit is the self-capacitive touch circuit, preparing the at least two flexible substrate layers; and preparing the touch circuit between the at least two flexible substrate layers comprises:

referring to FIG. 4, preparing a first flexible substrate layer 11;

preparing a touch electrode layer and a second flexible substrate layer 12 on the first flexible substrate layer 11, wherein the touch electrode layer is sandwiched between the first flexible substrate layer 11 and the second flexible substrate layer 12; wherein the touch electrode layer comprises a plurality of touch electrodes 14.

As the touch circuit is a mutual-capacitive touch circuit, preparing the at least two flexible substrate layers; and preparing the touch circuit between the at least two flexible substrate layers comprises:

referring to FIG. 5, preparing a first flexible substrate layer 11;

preparing a first touch electrode layer 15 and a second flexible substrate layer 12 on the first flexible substrate layer 11, wherein the first touch electrode layer 15 is sandwiched between the first flexible substrate layer 11 and the second flexible substrate layer 12;

preparing a second touch electrode layer 16 and a third flexible substrate layer 17 on the second flexible substrate layer 12, and the second touch electrode layer 16 is sandwiched between the second flexible substrate layer 12 and the third flexible substrate layer 17;

wherein a mutual capacitance is formed between the first touch electrode layer 15 and the second touch electrode layer 16.

In conclusion, the flexible substrate and the touch display panel provided by the present invention do not need to separately integrate the touch circuit and the driving elements together between the organic light emitting functional layer and the flexible substrate. Thus, the increase of the thickness of the driving element layer can be avoided. Moreover, the touch display panel does not need to be separately integrated on the outer side of the organic light emitting functional layer, thus inevitably increasing the thickness of the entire touch display panel. By simply integrating the touch circuit in the flexible substrate layer, the thickness of the flexible substrate layer can remain unchanged, but the overall thickness of the touch display panel can be reduced. Meanwhile, the touch circuit can be prepared in the flexible substrate, and then the driving circuit and the organic light emitting functional layer are prepared on the flexible substrate, which can reduce the preparation difficulty of the driving circuit, and thereby improving the production yield of the touch display panel.

The above content with the specific preferred embodiments of the present invention is further made to the detailed description, the specific embodiments of the present invention should not be considered limited to these descriptions. Those of ordinary skill in the art for the present invention, without departing from the spirit of the present invention, can make various simple deduction or replacement, should be deemed to belong to the scope of the present invention.

What is claimed is:

1. A flexible substrate, comprising at least two flexible substrate layers and a touch circuit disposed between the at least two flexible substrate layers.

2. The flexible substrate according to claim 1, wherein the touch circuit is a self-capacitive touch circuit or a mutual-capacitive touch circuit, and the self-capacitive touch circuit comprises a touch electrode layer, and the mutual-capacitive touch circuit comprises two touch electrode layers.

3. The flexible substrate according to claim 2, wherein as the touch circuit is the self-capacitive touch circuit, the at least two flexible substrate layers comprise a first flexible substrate layer and a second flexible substrate layer, and the touch electrode layer is arranged between the first flexible substrate layer and the second flexible substrate layer; the touch electrode layer comprises a plurality of touch electrodes.

4. The flexible substrate according to claim 2, wherein as the touch circuit is a mutual-capacitive touch circuit, the at least two flexible substrate layers comprise a first flexible substrate layer, a second flexible substrate layer and a third flexible substrate layer, and a first touch electrode layer is arranged between the first flexible substrate layer and the second flexible substrate layer, and a second touch electrode layer is arranged between the second flexible substrate layer and the third flexible substrate layer, and a mutual capacitance is formed between the first touch electrode layer and the second touch electrode layer.

5. The flexible substrate according to claim 2, wherein the touch electrode layer is made of a transparent conductive material, and the flexible substrate layer is made of a polyimide material or a polyester resin material.

6. The flexible substrate according to claim 5, wherein the transparent conductive material is one of an indium tin oxide material, a carbon nanotube and a nano silver wire material.

7. A touch display panel, comprising a flexible substrate, a driving element layer, an organic light emitting functional layer and thin film encapsulation layer located on the flexible substrate;
wherein the flexible substrate comprises at feast two flexible substrate layers and a touch circuit disposed between the at least two flexible substrate layers.

8. The touch display panel according to claim 7, wherein the touch circuit is a self-capacitive touch circuit or a mutual-capacitive touch circuit, and the self-capacitive touch circuit comprises a touch electrode layer, and the mutual-capacitive touch circuit comprises two touch electrode layers.

9. The touch display panel according to claim 8, wherein as the touch circuit is the self-capacitive touch circuit, the at least two flexible substrate layers comprise a first flexible substrate layer and a second flexible substrate layer, and the touch electrode layer is arranged between the first flexible substrate layer and the second flexible substrate layer; the touch electrode layer comprises a plurality of touch electrodes.

10. The touch display panel according to claim 8, wherein as the touch circuit is a mutual-capacitive touch circuit, the at least two flexible substrate layers comprise a first flexible substrate layer, a second flexible substrate layer and a third flexible substrate layer, and a first touch electrode layer is arranged between the first flexible substrate layer and the second flexible substrate layer, and a second touch electrode layer is arranged between the second flexible substrate layer and the third flexible substrate layer, and a mutual capacitance is formed between the first touch electrode layer and the second touch electrode layer.

11. The touch display panel according to claim 8, wherein the touch electrode layer is made of a transparent conductive material, and the flexible substrate layer is made of a polyimide material or a polyester resin material.

12. The touch display panel according to claim 11, wherein the transparent conductive material is one of an indium tin oxide material, a carbon nanotube and a nano silver wire material.

13. A manufacturing method of a flexible substrate, comprising:
preparing at least two flexible substrate layers; and
preparing a touch circuit between the at least two flexible substrate layers.

14. The manufacturing method of the flexible substrate according to claim 13, wherein the touch circuit is a self-capacitive touch circuit or a mutual-capacitive touch circuit, and the self-capacitive touch circuit comprises a touch electrode layer, and the mutual-capacitive touch circuit comprises two touch electrode layers.

15. The manufacturing method of the flexible substrate according to claim 14, wherein as the touch circuit is the self-capacitive touch circuit, preparing the at least two flexible substrate layers; and preparing the touch circuit between the at least two flexible substrate layers comprises: preparing a first flexible substrate layer; preparing a touch electrode layer and a second flexible substrate layer on the first flexible substrate layer, wherein the touch electrode layer is sandwiched between the first flexible substrate layer and the second flexible substrate layer; wherein the touch electrode layer comprises a plurality of touch electrodes;
as the touch circuit is a mutual-capacitive touch circuit, preparing the at least two flexible substrate layers; and preparing the touch circuit between the at least two flexible substrate layers comprises: preparing a first flexible substrate layer; preparing a first touch electrode layer and a second flexible substrate layer on the first flexible substrate layer, wherein the first touch electrode layer is sandwiched between the first flexible substrate layer and the second flexible substrate layer; preparing a second touch electrode layer and a third flexible substrate layer on the second flexible substrate layer, and the second touch electrode layer is sandwiched between the second flexible substrate layer and the third flexible substrate layer; wherein a mutual capacitance is formed between the first touch electrode layer and the second touch electrode layer.
